(19) United States
(12) Patent Application Publication
(10) Pub. No.: US 2026/0057153 A1
(43) Pub. Date: Feb. 26, 2026

(54) SYSTEMS AND METHODS FOR SIMULATING FLUID DYNAMICS ON QUANTUM COMPUTERS

(71) Applicant: QubitSolve Inc., Morgantown, WV (US)

(72) Inventor: Madhava Syamlal, Morgantown, WV (US)

(21) Appl. No.: 18/750,854

(22) Filed: Jun. 21, 2024

Related U.S. Application Data
(60) Provisional application No. 63/522,773, filed on Jun. 23, 2023.
(60) Provisional application No. 63/523,980, filed on Jun. 29, 2023.

(51) Int. Cl. G06F 30/28; G06N 10/20; G06N 10/60

(52) U.S. Cl. CPC G06F 30/28; G06N 10/20; G06N 10/60

(57) ABSTRACT

A system simulating fluid dynamics on quantum computers includes a quantum system, a processor, and a memory. The memory includes instructions stored thereon, which, when executed by the processor, cause the quantum system to: access initial conditions

$$( {θ}_{v}^{0} , {Θ}_{v}^{0} )$$

and boundary conditions

$$( {θ}_{v}^{b} , {Θ}_{v}^{b} ) ;$$

generate

$$\vert {\overline{{f}_{v}}}^{n} 〉$$

based on

$${θ}_{v}^{n}$$

by the quantum computer; generate

$$\vert {\overline{{f}_{v}}}^{b} 〉$$

based on

$${θ}_{v}^{b}$$

by the quantum computer; receive by the quantum computer values of

$${θ}_{v , new}^{n + 1}$$

from an optimizer and generate tentative values of

$$\vert {\overline{{f}_{v}}}^{n + 1} 〉 ;$$

generate by the quantum computer

$$〈 ℱ ( {\overline{{f}_{v}}}^{n} ) \vert {\overline{{f}_{v}}}^{n + 1} 〉$$

based on

$$\vert {\overline{{f}_{v}}}^{n} 〉$$

and the tentative values of

$$\vert {\overline{{f}_{v}}}^{n + 1} 〉 ;$$

generate by the quantum computer

$$〈 {\overline{{f}_{v}}}^{b} \vert {\overline{{f}_{v}}}^{n + 1} 〉$$

based on

$$\vert {\overline{{f}_{v}}}^{b} 〉$$

and the tentative values of

$$\vert {\overline{{f}_{v}}}^{n + 1} 〉 ;$$

determine cost function values Cᵥ based on a new value of

$${Θ}_{v , new}^{n + 1} ,$$

inner products

$$〈 {\overline{{f}_{v}}}^{b} \vert {\overline{{f}_{v}}}^{n + 1} 〉 ,$$

and

$$〈 ( {\overline{{f}_{v}}}^{n} ) \vert {\overline{{f}_{v}}}^{n + 1} 〉 ;$$

and determine by the optimizer values for

$$( {θ}_{v}^{n + 1} , {θ}_{v}^{n + 1} )$$

based on the cost function values Cᵥ.

### CROSS-REFERENCE TO RELATED APPLICATIONS

The present application claims the benefit of, and priority to, U.S. Provisional Patent Application Ser. No. 63/522,773, filed Jun. 23, 2023, and U.S. Provisional Patent Application Ser. No. 63/523,980, filed Jun. 29, 2023, the entire content of each is incorporated herein by reference.

### TECHNICAL FIELD

The present disclosure relates generally to the field of simulating fluid dynamics on quantum computers. More specifically, the present disclosure provides at least a system and method for solving fluid dynamics equations on quantum computers.

### BACKGROUND

Simulating fluid dynamics involves using mathematical models and computational methods to predict the behavior of fluids (liquids and gases). It aims to simulate how fluids flow, interact with each other and their surroundings, and how forces such as viscosity and turbulence affect their motion. This process typically involves solving complex equations like the Navier-Stokes equations numerically, taking into account parameters like fluid density, velocity, and pressure at various points in a simulated domain. These simulations are often used in engineering (e.g., designing airplanes and cars), weather forecasting, and understanding natural phenomena such as ocean currents and atmospheric flows.

Accordingly, there is interest in solving fluid dynamics equations on quantum computers.

### SUMMARY

An aspect of the present disclosure provides a system simulating fluid dynamics on quantum computers. The system includes a quantum system, a processor, and a memory. The memory includes instructions stored thereon, which, when executed by the processor, cause the quantum system to: access initial conditions

$$( {θ}_{v}^{0} , {Θ}_{v}^{0} )$$

and boundary conditions

$$( {θ}_{v}^{b} , {Θ}_{v}^{b} ) ;$$

generate

$$\vert {\overline{{f}_{v}}}^{n} 〉$$

based on

$${θ}_{v}^{n}$$

by the quantum computer; generate

$$\vert {\overline{{f}_{v}}}^{b} 〉$$

based on

$${θ}_{v}^{b}$$

by the quantum computer; receive by the quantum computer values of

$${θ}_{v , new}^{n + 1}$$

from an optimizer and generate tentative values of

$$\vert {\overline{{f}_{v}}}^{n + 1} 〉 ;$$

generate by the quantum computer

$$〈 ( {\overline{{f}_{v}}}^{n} ) \vert {\overline{{f}_{v}}}^{n + 1} 〉$$

based on

$$\vert {\overline{{f}_{v}}}^{n} 〉$$

and the tentative values of

$$\vert {\overline{{f}_{v}}}^{n + 1} 〉 ;$$

generate by the quantum computer

$$〈 {\overline{{f}_{v}}}^{b} \vert {\overline{{f}_{v}}}^{n + 1} 〉$$

based on

$$\vert {\overline{{f}_{v}}}^{b} 〉$$

and the tentative values of

$$\vert {\overline{{f}_{v}}}^{n + 1} 〉 ;$$

determine cost function values Cᵥ based on a new value of

$${Θ}_{v , new}^{n + 1} ,$$

inner products

$$〈 {\overline{{f}_{v}}}^{b} \vert {\overline{{f}_{v}}}^{n + 1} 〉 ,$$

and

$$〈 ( {\overline{{f}_{v}}}^{n} ) \vert {\overline{{f}_{v}}}^{n + 1} 〉 ;$$

determine, by the optimizer, values for

$$( {θ}_{v}^{n + 1} , {Θ}_{v}^{n + 1} )$$

based on the cost function values Cᵥ.

In accordance with aspects of the disclosure, the instructions, when executed by the processor further cause the system to generate a visualization based on

$$( {θ}_{v}^{n + 1} , {Θ}_{v}^{n + 1} ) .$$

In an aspect of the present disclosure, initial conditions

$$( {θ}_{v}^{0} , {Θ}_{v}^{0} )$$

and boundary conditions

$$( {θ}_{v}^{b} , {Θ}_{v}^{b} )$$

are determined by: accessing a grid representing a fluid flow around an object, where the grid includes N_{grid} grid points, and where initial values for velocity (uᵢ) and density (ρ) are assigned at every grid point; and performing transformations to convert velocity (uᵢ) and density (ρ) into initial conditions

$$( {θ}_{v}^{0} , {Θ}_{v}^{0} )$$

and boundary conditions

$$( {θ}_{v}^{b} , {Θ}_{v}^{b} ) .$$

In another aspect of the present disclosure, where performing transformations to convert velocity (uᵢ) and density (ρ) into the parameters that require solving may be performed by solving for

$${f}_{v}^{n} \to {f}_{v}^{n + 1}$$

using Lattice Boltzmann Method (LBM), where fᵥ is the v^{th} discretized particle velocity distribution function.

In yet another aspect of the present disclosure, where performing transformations to convert velocity (uᵢ) and density (ρ) into the parameters that require solving may be further performed by recovering velocity (uᵢ) and density (ρ) into moments of fᵥ:ρ=Σᵥfᵥ, and

$${u}_{l} = \frac{1}{ρ} {\sum }_{v} {c}_{l v} {f}_{v} ,$$

where cₗᵥ is the lattice-particle velocity.

In accordance with aspects of the disclosure, a plurality of

$$\vert {\overline{{f}_{v}}}^{n + 1} 〉$$

may be generated.

In an aspect of the present disclosure, where generating tentative values of

$$\vert {\overline{{f}_{v}}}^{n + 1} 〉$$

may use the Lattice Boltzmann Method (LBM) to solve for

$${f}_{v}^{n} \to {f}_{v}^{n + 1} ,$$

where fᵥ is a v^{th} discretized particle velocity distribution function.

In another aspect of the present disclosure, when generating tentative values of

$$\vert {\overline{{f}_{v}}}^{n + 1} 〉$$

the instructions, when executed by the processor, may further cause the system to recover the CFD variables from the moments of fᵥ:ρ=Σᵥfᵥ, and

$${u}_{l} = \frac{1}{ρ} {\sum }_{v} {c}_{l v} {f}_{v} ,$$

where cₗᵥ is the lattice-particle velocity.

In yet another aspect of the present disclosure, when generating tentative values of

$$\vert {\overline{{f}_{v}}}^{n + 1} 〉$$

the instructions, when executed by the processor, may further cause the system to encode fᵥ into the amplitudes of a quantum state.

In accordance with aspects of the disclosure, when generating tentative values of

$$\vert {\overline{{f}_{v}}}^{n + 1} 〉$$

the instructions, when executed by the processor, may further cause the system to: normalize, by the classical computer, values of fᵥ as f̅ₖᵥ=fₖᵥ/Θᵥ, where fₖᵥ is the value of fᵥ at grid point k, and Θᵥ is a 2-norm; and encode fᵥ as:

$$\vert \overline{{f}_{v}} 〉 = {\sum }_{k = 0}^{{2}^{{N}_{q} - 1}} {\overline{f}}_{k v} \vert k 〉 ,$$

where N_{q}≈log(N_{grid}) and |k [symbol] is a k^{th} computational basis state.

An aspect of the present disclosure provides a processor-implemented method for simulating fluid dynamics on quantum computers. The method includes accessing initial conditions

$$( {θ}_{v}^{0} , {Θ}_{v}^{0} )$$

and boundary conditions

$$( {θ}_{v}^{b} , {Θ}_{v}^{b} ) ;$$

generating

$$\vert {\overline{{f}_{v}}}^{n} 〉$$

based on

$${θ}_{v}^{n}$$

by a quantum computer; generating

$$\vert {\overline{{f}_{v}}}^{b} 〉$$

based on

$${θ}_{v}^{b}$$

by the quantum computer; receiving by the quantum computer values of

$${θ}_{v ,}^{n + 1}$$

from an optimizer and generate tentative values of

$$\vert {\overline{{f}_{v}}}^{n + 1} 〉$$

based on

$${θ}_{v , new}^{n + 1} ;$$

generating by the quantum computer

$$( ℱ ( {\overline{{f}_{v}}}^{n} ) \vert {\overline{{f}_{v}}}^{n + 1} 〉$$

based on

$$\vert {\overline{{f}_{v}}}^{n} 〉$$

and the tentative values of

$$\vert {\overline{{f}_{v}}}^{n + 1} 〉 ;$$

generating by the quantum computer

$$〈 {\overline{{f}_{v}}}^{b} \vert {\overline{{f}_{v}}}^{n + 1} 〉$$

based on

$$\vert {\overline{{f}_{v}}}^{b} 〉$$

and the tentative values of

$$\vert {\overline{{f}_{v}}}^{n + 1} 〉 ;$$

determining cost function values Cᵥ based on a new value of

$${Θ}_{v , new}^{n + 1} ,$$

inner products

$$〈 {\overline{{f}_{v}}}^{b} \vert {\overline{{f}_{v}}}^{n + 1} 〉 ,$$

and

$$〈 ℱ ( {\overline{{f}_{v}}}^{n} ) \vert {\overline{{f}_{v}}}^{n + 1} 〉 ;$$

determining, by the optimizer, values for

$$( {θ}_{v}^{n + 1} , {Θ}_{v}^{n + 1} )$$

based on the cost function values Cᵥ.

In another aspect of the present disclosure, the method may further include generating a visualization based on

$$( {θ}_{v}^{n + 1} , {Θ}_{v}^{n + 1} ) .$$

In yet another aspect of the present disclosure, the method may further include: determining initial conditions

$$( {θ}_{v}^{0} , {Θ}_{v}^{0} )$$

and boundary conditions

$$( {θ}_{v}^{b} , {Θ}_{v}^{b} )$$

by: accessing a grid representing a fluid flow around an object, wherein the grid includes N_{grid} grid points; and performing transformations to convert velocity (uᵢ) and density (ρ) into initial conditions

$$( {θ}_{v}^{0} , {Θ}_{v}^{0} )$$

and boundary conditions

$$( {θ}_{v}^{b} , {Θ}_{v}^{b} ) .$$

Initial values for velocity (uᵢ) and density (ρ) are assigned at every grid point.

In an aspect of the present disclosure, performing transformations to convert velocity (uᵢ) and density (ρ) may be performed by solving for

$${f}_{v}^{n} \to {f}_{v}^{n + 1}$$

using Lattice Boltzmann Method (LBM), where fᵥ is the v^{th} discretized particle velocity distribution function.

In another aspect of the present disclosure, where performing transformations to convert velocity (uᵢ) and density (ρ) into the parameters may be further performed by recovering velocity (uᵢ) and density (ρ) from moments of fᵥ:ρ=Σᵥfᵥ, and

$${u}_{l} = \frac{1}{ρ} {\sum }_{v} {c}_{lv} {f}_{v} ,$$

where cₗᵥ is the lattice-particle velocity.

In an aspect of the present disclosure, when generating tentative values of

$$\vert {\overline{f}}_{v}^{n + 1} 〉$$

the method may further include encoding fᵥ into the amplitudes of a quantum state.

In another aspect of the present disclosure, when generating tentative values of

$$\vert {\overline{f}}_{v}^{n + 1} 〉$$

the method may further include: normalizing values of fᵥ as f̅ₖᵥ=fₖᵥ/Θᵥ, where fₖᵥ is the value of fᵥ at grid point k, and Θᵥ is a 2-norm; and encoding fᵥ as:

$$\vert {\overline{f}}_{v} 〉 = {\sum }_{k = 0}^{{2}^{{N}_{q} - 1}} {\overline{f}}_{kv} \vert k 〉 ,$$

where N_{q}≈log(N_{grid}) and |k [symbol] is a k^{th} computational basis state of a quantum system.

An aspect of the present disclosure provides a non-transitory computer-readable storage medium storing a program for simulating fluid dynamics on quantum computers. The method includes accessing initial conditions

$$( {θ}_{v}^{0} , {Θ}_{v}^{0} )$$

and boundary conditions

$$( {θ}_{v}^{b} , {Θ}_{v}^{b} ) ;$$

generating

$$\vert {\overline{f}}_{v}^{n} 〉$$

based on

$${θ}_{v}^{n}$$

by a quantum computer; generating

$$\vert {\overline{f}}_{v}^{b} 〉$$

based on

$${θ}_{v}^{b}$$

by the quantum computer; receiving by the quantum computer values of

$${θ}_{v , new}^{n + 1}$$

from an optimizer and generate tentative values of

$$\vert {\overline{f}}_{v}^{n + 1} 〉$$

based on

$${θ}_{v , new}^{n + 1} ;$$

generating by the quantum computer

$$〈 ( {\overline{{f}_{v}}}^{n} ) \vert {\overline{{f}_{v}}}^{n + 1} 〉$$

based on

$$\vert {\overline{{f}_{v}}}^{n} 〉$$

and the tentative values of

$$\vert {\overline{{f}_{v}}}^{n + 1} 〉 ;$$

generating by the quantum computer

$$〈 {\overline{{f}_{v}}}^{b} \vert {\overline{{f}_{v}}}^{n + 1} 〉$$

based on

$$\vert {\overline{{f}_{v}}}^{b} 〉$$

and the tentative values of

$$\vert {\overline{{f}_{v}}}^{n + 1} 〉 ;$$

determining cost function values Cᵥ based on a new value of

$${Θ}_{v , new}^{n + 1} ,$$

inner products

$$〈 {\overline{{f}_{v}}}^{b} \vert {\overline{{f}_{v}}}^{n + 1} 〉 ,$$

and

$$〈 ( {\overline{{f}_{v}}}^{n} ) \vert {\overline{{f}_{v}}}^{n + 1} 〉 ;$$

and determining, by the optimizer, values for

$$( {θ}_{v}^{n + 1} , {Θ}_{v}^{n + 1} )$$

based on the cost function values Cᵥ.

Further details and aspects of exemplary aspects of the present disclosure are described in more detail below with reference to the appended figures.

### BRIEF DESCRIPTION OF THE DRAWINGS

A better understanding of the features and advantages of the present disclosure will be obtained by reference to the following detailed description that sets forth illustrative aspects, in which the principles of the present disclosure are utilized, and the accompanying drawings of which:

FIG. 1 is a diagram of an exemplary system for simulating fluid dynamics on quantum computers, in accordance with examples of the present disclosure;

FIG. 2 is a schematic diagram of an exemplary processing system diagram for use with the system of FIG. 1, in accordance with examples of the present disclosure;

FIG. 3 is a diagram of a method for simulating fluid dynamics using the system of FIG. 1, in accordance with examples of the present disclosure;

FIG. 4 is a flow diagram that illustrates the transformations utilized to convert computational fluid dynamics variables into the parameters that require solving, in accordance with examples of the present disclosure;

FIG. 5 is a diagram illustrating preparing |f̅ᵥ [symbol] with the help of a parametrized quantum circuit (PQC) 500, in accordance with examples of the present disclosure;

FIG. 6 is a diagram illustrating a streaming operation of the system of FIG. 1, in accordance with examples of the present disclosure;

FIG. 7 is a flow diagram illustrating the mapping of the method of FIG. 3 to the system of FIG. 1, in accordance with examples of the present disclosure;

FIG. 8 is a graph illustrating advantages provided by the system of FIG. 1, in accordance with examples of the present disclosure;

FIGS. 9 and 10 are graphs illustrating examples of how the optimizer of the system of FIG. 7 reduces cost function values for two field variables, in accordance with examples of the present disclosure;

FIG. 11 is a diagram illustrating an example of a quantum circuit for calculating an inner product, in accordance with examples of the present disclosure; and

FIG. 12 is a graph illustrating a comparison between classical computational fluid dynamics (CFD) and the variational quantum CFD (VQCFD) used by the system of FIG. 1, in accordance with examples of the present disclosure.

### DETAILED DESCRIPTION

The present disclosure relates generally to the field of quantum operations. More specifically, the present disclosure provides at least a system and method simulating fluid dynamics on quantum computers.

Aspects of the present disclosure are described in detail with reference to the drawings wherein like reference numerals identify similar or identical elements.

Although the present disclosure will be described in terms of specific examples, it will be readily apparent to those skilled in this art that various modifications, rearrangements, and substitutions may be made without departing from the spirit of the present disclosure. The scope of the present disclosure is defined by the claims appended hereto.

For purposes of promoting an understanding of the principles of the present disclosure, reference will now be made to exemplary aspects illustrated in the drawings, and specific language will be used to describe the same. It will nevertheless be understood that no limitation of the scope of the present disclosure is thereby intended. Any alterations and further modifications of the novel features illustrated herein, and any additional applications of the principles of the present disclosure as illustrated herein, which would occur to one skilled in the relevant art and having possession of this disclosure, are to be considered within the scope of the present disclosure.

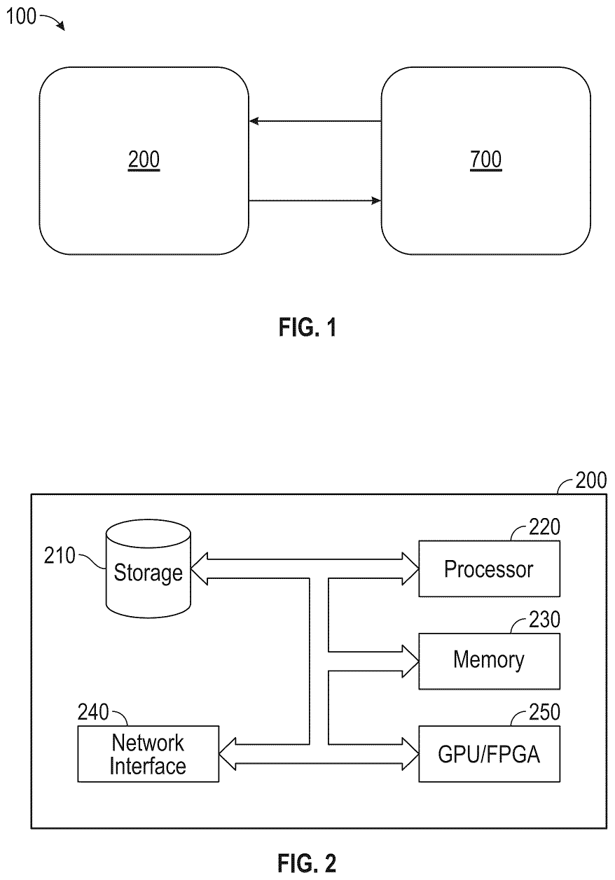

Referring to FIG. 1, a diagram of an example system 100 for simulating fluid dynamics on quantum computers is shown. System 100 generally includes a quantum computer 700 and a classical computer 200 (FIG. 2).

Computational fluid dynamics (CFD) is a technique for solving the Navier-Stokes equations. Rather than analyzing the entire airflow around a car as one continuous flow, CFD divides the flow into small sections (e.g., a mesh), resembling a grid of tiny boxes. Each box on the grid represents a fraction of the airflow around an object. Although described herein as boxes, the grid may be a structured mesh (e.g., boxes) or unstructured mesh (e.g., triangles, tetrahedra). The grid includes N_{grid} grid points. CFD is used to determine the behavior of the air (e.g., or other fluid) at each grid point, that is, the changes in velocity (uᵢ) and density (ρ) over time. The system 100 assigns the initial values for uᵢ and ρ at every grid point. Then, the changes from one time step to the next are computed, that is,

$$( {ρ}^{n} , {u}_{i}^{n} ) \to ( {ρ}^{n + 1} , {u}_{i}^{n + 1} ) ,$$

which states that values of density and velocity at time step n+1 are calculated from their values at timestep n. The computations account for the interactions between neighboring grid points, where the values at one grid point influence the values in its neighboring grid points, much like how the air in one part of the flow affects the air in nearby sections. System 100 of FIG. 1 employs variational quantum CFD (VQCFD). System 100 solves the technical problem that exists in classical CFD systems where some problems are unsolvable because they are too expensive with regards to processing resources. For example, simulating fluid dynamics for an airplane taking off and/or landing is too expensive, resource-wise, for classical CFD systems. However, such a simulation is possible using disclosed systems and methods because the resource heavy portions can be performed by the quantum computer in an efficient manner as described below.

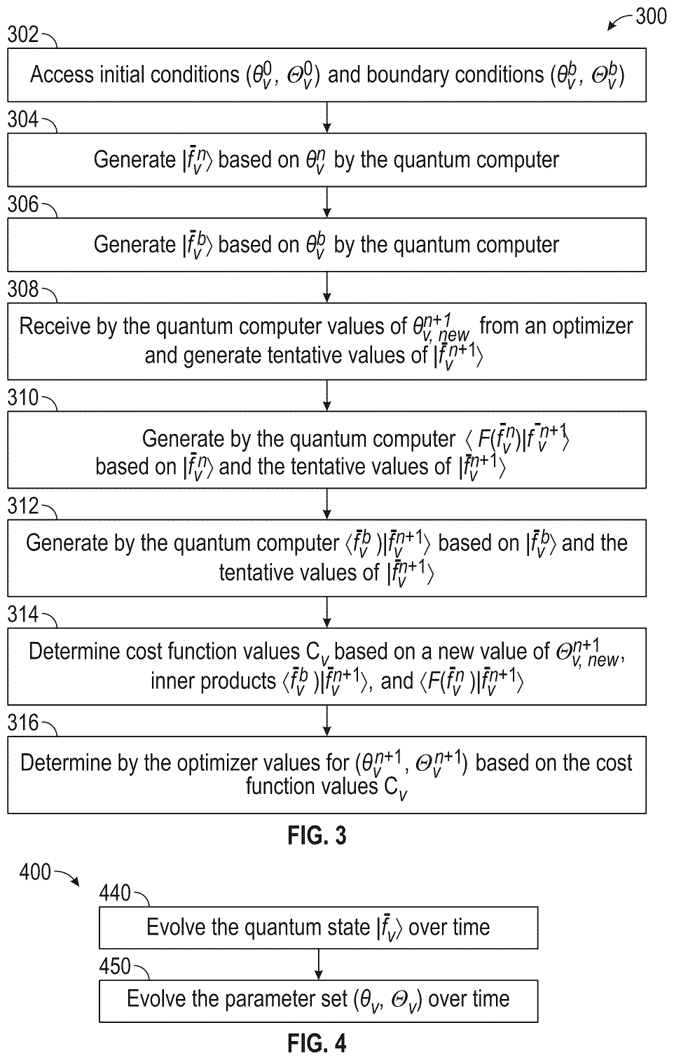

Referring now to FIG. 2, exemplary components of the classical computer 200 are shown. The classical computer 200 generally includes a storage or database 210, one or more processors 220, at least one memory 230, and a network interface 240. In aspects, the classical computer 200 may include a graphical processing unit (GPU) 250. The processor 210 and a memory 211, include instructions stored thereon, which, when executed by the processor 210, cause the quantum system 100 to perform the steps of method 300 of FIG. 3.

The database 210 can be located in storage. The term “storage” may refer to any device or material from which information may be capable of being accessed, reproduced, and/or held in an electromagnetic or optical form for access by a computer processor. Storage may be, for example, volatile memory such as RAM, non-volatile memory, which permanently holds digital data until purposely erased, such as flash memory, magnetic devices such as hard disk drives, and optical media such as a CD, DVD, Blu-ray Disc™, or the like.

In aspects, data may be stored on the classical computer 200, including, for example, user accounts, permissions, licensing documentation, and/or other data. The data can be stored in the database 210 and sent via the system bus to the processor 220. The database 210 may store information in a manner that satisfies information security standards and/or government regulations, such as Systems and Organization Controls (e.g., SOC 2), General Data Protection Regulation (GDPR), and/or International Organization for Standardization (ISO) standards.

As will be described in more detail later herein, the processor 220 executes various processes based on instructions that can be stored in the at least one memory 230 and utilizing the data from the database 210. With reference also to FIG. 1, a request from a user device, such as a mobile device or a client computer, can be communicated to the classical computer 200 through the network interface 240. The illustration of FIG. 2 is exemplary, and persons skilled in the art will understand that other components may exist in classical computer 200. Such other components are not illustrated for clarity of illustration.

Referring to FIG. 3, a method 300 for simulating fluid dynamics on quantum computers using the system of FIG. 1 is shown. The system 100 for system for simulating fluid dynamics on quantum computers may include a processor and a memory, including instructions stored thereon, which when executed by the processor 210, cause the quantum system 300 to perform the steps of method 300.

Initially, system 100 causes processor 210 to access a grid representing a fluid flow around an object, wherein the grid includes N_{grid} grid points. Initial values for velocity (uᵢ) and density (ρ) are assigned at every grid point. Next, system 100 causes processor 210 to perform transformations to convert velocity (uᵢ) and density (ρ) into parameters

$$( {θ}_{v}^{0} , {Θ}_{v}^{0} ) .$$

For example, initial conditions

$$( {θ}_{v}^{0} , {Θ}_{v}^{0} )$$

and boundary conditions

$$( {θ}_{v}^{b} , {Θ}_{v}^{b} )$$

may be determined by accessing a grid representing a fluid flow around an object, wherein the grid includes N_{grid} grid points, wherein initial values for velocity (uᵢ) and density (ρ) are assigned at every grid point; and performing transformations to convert velocity (uᵢ) and density (ρ) into initial conditions

$$( {θ}_{v}^{0} , {Θ}_{v}^{0} )$$

and boundary conditions

$$( {θ}_{v}^{b} , {Θ}_{v}^{b} ) .$$

At step 302, the quantum computer 700 accesses the initial conditions

$$( {θ}_{v}^{0} , {Θ}_{v}^{0} )$$

and the boundary conditions

$$( {θ}_{v}^{b} , {Θ}_{v}^{b} ) .$$

At step 304, the quantum computer 700 generates

$$\vert {\overline{{f}_{v}}}^{n} 〉$$

based on

$${θ}_{v}^{n} .$$

At step 306, the quantum computer 700 generates

$$\vert {\overline{{f}_{v}}}^{b} 〉$$

based on

$${θ}_{v}^{b}$$

by the quantum computer.

At step 308, the quantum computer 700 receives values of

$${θ}_{v , new}^{n + 1}$$

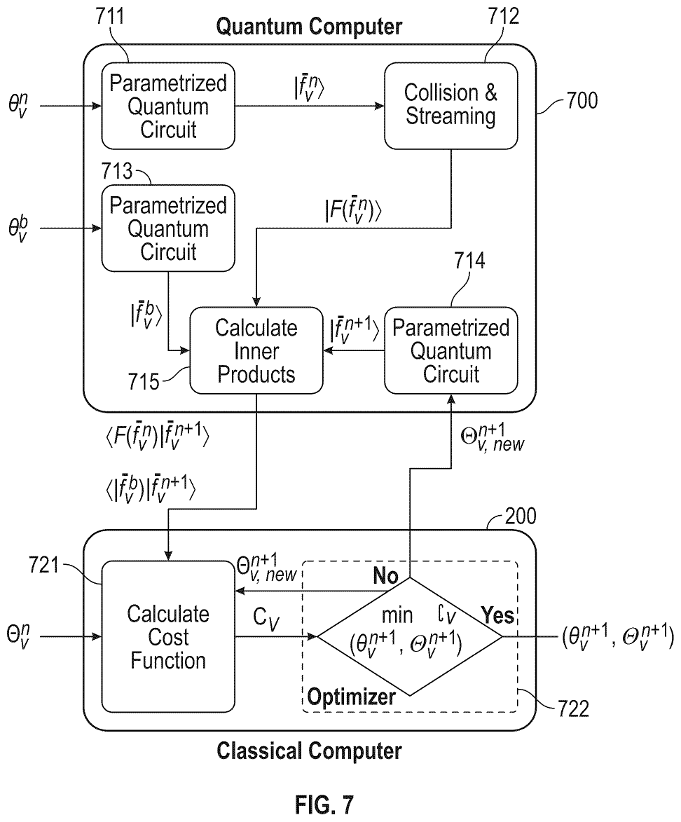

from an optimizer 722 (FIG. 7) and generate tentative values of

$$\vert {\overline{{f}_{v}}}^{n + 1} 〉 .$$

At step 310, the quantum computer 700 generates

$$〈 ( {\overline{{f}_{v}}}^{n} ) \vert {\overline{{f}_{v}}}^{n + 1} 〉$$

based on

$$\vert {\overline{{f}_{v}}}^{n} 〉$$

and the tentative values of

$$\vert {\overline{{f}_{v}}}^{n + 1} 〉 .$$

At step 312, the quantum computer 700 generates by the quantum computer

$$〈 {\overline{{f}_{v}}}^{b} \vert {\overline{{f}_{v}}}^{n + 1} 〉$$

based on

$$\vert {\overline{{f}_{v}}}^{b} 〉$$

and the tentative values of

$$\vert {\overline{{f}_{v}}}^{n + 1} 〉 .$$

At step 314, system 100 causes processor 210 to determine cost function values Cᵥ based on a new value of

$${Θ}_{v , new}^{n + 1} ,$$

inner products

$$〈 {\overline{{f}_{v}}}^{b} \vert {\overline{{f}_{v}}}^{n + 1} 〉 ,$$

and

$$〈 ℱ ( {\overline{{f}_{v}}}^{n} ) \vert {\overline{{f}_{v}}}^{n + 1} 〉 .$$

At step 316, system 100 causes processor 210 to determine, by the optimizer, values for

$$( {θ}_{v ′}^{n + 1} ′ {θ}_{v}^{n + 1} )$$

based on the cost function values Cᵥ.

In aspects, system 100 may cause processor 210 to generate a visualization based on

$$( {θ}_{v}^{n + 1} , {Θ}_{v}^{n + 1} ) .$$

Although visualization is used as an example, other uses for the values

$$( {θ}_{v}^{n + 1} , {Θ}_{v}^{n + 1} )$$

are contemplated.

Referring to FIG. 4, a flow diagram that illustrates the transformations utilized to convert CFD variables into the parameters that require solving in accordance with the present disclosure is shown.

The system 100 uses the Lattice Boltzmann Method (LBM), which solves for

$${f}_{v}^{n} \to {f}_{v}^{n + 1} ,$$

where fᵥ is the v^{th} discretized particle velocity distribution function.

LBM is a computational technique used for simulating fluid dynamics at the mesoscopic scale. LBM is a reliable method that doesn't require a Poisson solver, can manage complex and moving boundary conditions, and is adequate for aeroacoustic simulations.

Unlike traditional methods that solve the Navier-Stokes equations directly, LBM operates on a lattice grid where fluid particles (represented as distributions) move and collide according to simplified kinetic rules. These collisions mimic macroscopic fluid behavior, such as viscosity and momentum transfer. LBM is advantageous for its ability to handle complex geometries and boundaries with ease, parallelization for efficient computation, and suitability for modeling multi-phase flows and complex fluid interactions. LBM conducts all non-linear calculations at individual grid points, which highly benefits quantum computing.

The system 100 recovers the CFD variables from the moments of fᵥ:ρ=Σᵥfᵥ, and

$${u}_{l} = \frac{1}{ρ} {\sum }_{v} {c}_{lv} {f}_{v} ,$$

where cₗᵥ is the lattice-particle velocity.

Next, at operation 440, the system evolves the quantum state |f̅ᵥ [symbol] over time. System 100 encodes fᵥ into the amplitudes of a quantum state. First, the values of fᵥ are normalized like f̅ₖᵥ=fₖᵥ/Θᵥ, where fₖᵥ is the value of fᵥ at grid point k, and Θᵥ is the 2-norm. Then, fᵥ is encoded as:

$$\vert \overline{{f}_{v}} 〉 = {\sum }_{k = 0}^{{2}^{{N}_{q} - 1}} {\overline{f}}_{kv} \vert k 〉$$

where N_{q}≈log(N_{grid}) and |k [symbol] is the k^{th} computational basis state of the quantum system.

In another aspect of the present disclosure, system 100 stores f̅ₖᵥ values, such that an LBM operation called “streaming” is efficient. For example, a three-dimensional 4×4×4 grid may be stored in a 6-qubit register as |x₁x₀y₁y₀z₁z₀ [symbol] such that the computational basis states encode the coordinate directions in the order x, y, and z.

Next at operation 450, system 100 evolves the parameter set (θᵥ, Θᵥ) over time. In aspects, |f̅ᵥ [symbol] may be expressed as a function of parameters

$${θ}_{v}^{n} .$$

In aspects, system 100 solves for

$$( {θ}_{v}^{n} , {Θ}_{v}^{n} ) \to ( {θ}_{v}^{n + 1} , {Θ}_{v}^{n + 1} ) ,$$

which is the equivalent of solving the Navier-Stokes equations.

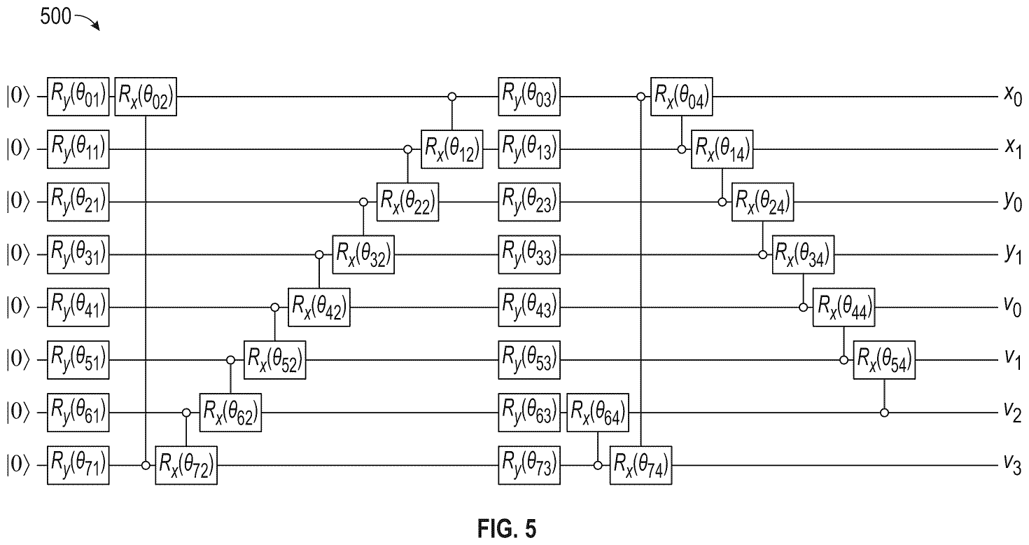

Referring to FIG. 5, an example diagram illustrating preparing |f̅ᵥ [symbol] with the help of a parametrized quantum circuit (PQC) 500 is shown. PQC 500 takes as input |0^{⊗N}^{_{q}}, the default value of qubits on quantum computers, and

$${θ}_{v}^{n} ,$$

a vector consisting of θ₀₁, θ₀₂, . . . θ₇₄, the parameters of PQC gates. Those skilled in the art can design PQCs in various other ways.

The system 100 modifies the LBM equation as follows:

$${Θ}_{v}^{n + 1} \vert {\overline{{f}_{v}}}^{n + 1} 〉 = ( 1 - \frac{Δ t}{τ} ) {Θ}_{v}^{n} \vert 〉 + \frac{Δ t}{τ} {Θ}_{v}^{n} \vert 〉 , \qquad ( 1 )$$

where the subscript [symbol] denotes a vector that has been streamed, i.e., its values have been shifted on the spatial grid by cₗᵥΔt.

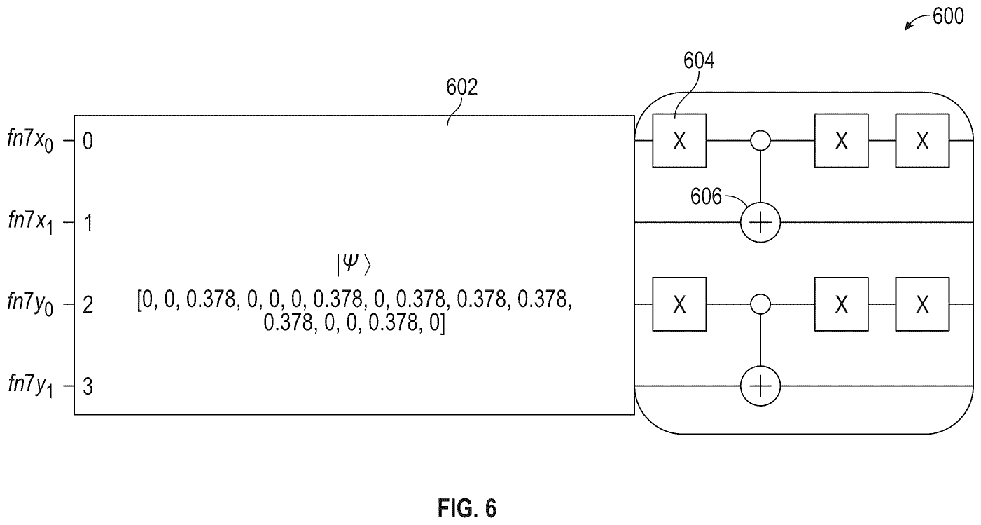

FIG. 6 shows an example of the streaming operation, taking |f̅₇ [symbol] on a 2×2 grid as an example. Qubits are initialized 602 for processing by the streaming circuit 600. Streaming circuit 600 includes not-gates 604 and control-not-gates 606. In this example, streaming circuit 600 is streaming values in the south-west (down-left) direction, the direction in which |f̅₇ [symbol] must be streamed. Those skilled in the art will appreciate how this method can be applied to stream |f̅ᵥ [symbol] in the v^{th} direction, as well as to do so in three dimensions.

In aspects, system 100 may utilize a variational method for solving Equation (1), which involves minimizing a cost function, derived by taking an inner product of Equation (1) with

$$\vert {\overline{{f}_{v}}}^{n + 1} 〉 .$$

The system 100 may account for the non-linear function [symbol] in the cost function. In aspects, the system 100 may incorporate the boundary conditions in the cost function.

Referring to FIG. 7, a flow diagram illustrating the mapping of the method 300 of FIG. 3 to a hybrid system consisting of a quantum computer 700 and a classical computer 200. Although a specific sequence of calculations is described here, the many variations and alterations to the following sequence are within the scope of the present disclosure. Those skilled in the art will appreciate how to develop a sequence suitable for a particular quantum-classical computer system.

FIG. 7 illustrates the data flow within the quantum computer 700 and the classical computer 200 and between them during time-stepping, that is, advancing a time step. Time-stepping accounts for most of the computational effort of this method. To begin time-stepping, parameters

$$( {θ}_{v}^{0} , {Θ}_{v}^{0} )$$

and

$$( {θ}_{v}^{b} , {Θ}_{v}^{b} )$$

representing the initial conditions and boundary conditions, respectively, are required. The parameters

$${Θ}_{v}^{0}$$

and

$${Θ}_{v}^{b} ,$$

the 2-norms, are calculated on the classical computer 200 from the initial and boundary conditions specified by the CFD user. The parameters

$${θ}_{v}^{0}$$

and

$${θ}_{v}^{b}$$

are determined by training parameterized quantum circuits on the specified initial and boundary conditions.

The time-stepping begins with

$$( {θ}_{{V}^{2}}^{0} , {Θ}_{v}^{0} )$$

obtained from the initial conditions, and the first timestep generates

$$( {θ}_{v}^{1} , {Θ}_{v}^{1} ) .$$

The next timestep uses

$$( {θ}_{v}^{1} , {Θ}_{v}^{1} )$$

as input and generates

$$( {θ}_{v}^{2} , {Θ}_{v}^{2} )$$

as output. This process is continued, and at any timestep n,

$$( {θ}_{v}^{n} , {Θ}_{v}^{n} )$$

is advanced to

$$( {θ}_{v}^{n + 1} , {Θ}_{v}^{n + 1} ) .$$

This in effect advances

$$\vert {\overline{{f}_{v}}}^{n} 〉$$

to

$$\vert {\overline{{f}_{v}}}^{n + 1} 〉 ,$$

which is the equivalent of advancing

$$( {ρ}^{n} , {u}_{i}^{n} )$$

to

$$( {ρ}^{n + 1} , {u}_{i}^{n + 1} ) ,$$

that is solving the Navier-Stokes equations. This sequence of calculations continues until a duration specified by the CFD user is simulated. The sequence of calculations for |f̅ᵥ [symbol] are as follows.

Initially, at operation 711 the quantum computer 700 takes

$${θ}_{v}^{n}$$

as input and generates

$$\vert {\overline{{f}_{v}}}^{n} 〉$$

as output. Multiple copies of

$$\vert {\overline{{f}_{v}}}^{n} 〉$$

must be generated because they are required in non-linear calculations and because copying of a quantum state is not possible per the no-cloning theorem. Next, at operation 712 the quantum computer 700 uses multiple copies of

$$\vert {\overline{{f}_{v}}}^{n} 〉$$

as input and produces terms

$$\vert τ ( {\overline{{f}_{v}}}^{n} ) 〉$$

that result from collision and streaming operations.

Next, at operation 713, the quantum computer 700 takes

$${θ}_{v}^{b}$$

generated from the wall boundary condition as input and generates

$$\vert {\overline{{f}_{v}}}^{b} 〉$$

as the output.

Next, at operation 714, the quantum computer 700 receives new values of

$${θ}_{v , new}^{n + 1}$$

from an optimizer 722 of the classical computer 200 and generates tentative values of

$$\vert {\overline{{f}_{v}}}^{n + 1} 〉$$

as output. Again, multiple copies of

$$- \vert {\overline{{f}_{v}}}^{n + 1} 〉$$

are generated.

The output of operations 712 and 714 are provided as input to operation 715, where quantum computer 700 generates as an output the inner products

$$( ( {\overline{{f}_{v}}}^{n} ) \vert {\overline{{f}_{v}}}^{n + 1} 〉 .$$

Additionally, the output of operations 713 and 714 are provided as input to operation 715, which generates the inner products

$$( {\overline{{f}_{v}}}^{b} \vert {\overline{{f}_{v}}}^{n + 1} 〉$$

as output. The term “inner product” herein refers to the multiplication of the elements of a vector with the corresponding elements of one or more vectors, followed by the summation of all the products.

The inner products from operation 715 are provided as input to the classical computer 200 for operation 721. Many inner products are required for each iteration of the optimizer 722 at each timestep. The inner products may be generated in a single call to the quantum computer 700 or in multiple calls. Those skilled in the art will appreciate how to make the calls efficiently to suit a particular quantum computer system.

Next, at operation 721, the classical computer 200 calculates cost function values Cᵥ based on the new value of

$${Θ}_{v , new}^{n + 1}$$

from the optimizer 722.

The cost function values Cᵥ are provided as input to the optimizer 722. There are many options for optimizers, and those skilled in the art will appreciate how to choose a suitable optimizer. The optimizer checks whether Cᵥ values have reached minimum values. If they have not, the optimizer 722 updates the values of

$${θ}_{v , new}^{n + 1} ,$$

which are provided as input to the quantum computer 700 for operation 714, and updates the values of

$${Θ}_{v , new}^{n + 1} ,$$

which are provided as input to operation 721. If Cᵥ values have reached minimum values, the optimizer 722 outputs the values

$$( {θ}_{v}^{n + 1} , {Θ}_{v}^{n + 1} )$$

and the timestep advancement is complete.

The values

$$( {θ}_{v}^{n + 1} , {Θ}_{v}^{n + 1} )$$

may be used in visualizing the data. For example, particularly in the context of visualizing airflow, there are several approaches you can take to analyze and visualize the data, such as flow visualization or volume rendering.

For example, velocity vectors may be plotted at different points in the domain to visualize the direction and magnitude of fluid flow. The system 100 may draw lines that are tangent to the velocity field at each point, which provides a visualization of the flow path. The system 100 may display the trajectories of particles in the flow over time, which helps in understanding how fluid elements move. In aspects, the system 100 may display streak lines, and/or contour plots.

In aspects, the system 100 may use

$$( {θ}_{v}^{n + 1} , {Θ}_{v}^{n + 1} )$$

for volume rendering. For three-dimensional flow fields, techniques like volume rendering can be used to display the entire flow volume based on properties like velocity magnitude or vorticity.

In aspects, the system 100 may use

$$( {θ}_{v}^{n + 1} , {Θ}_{v}^{n + 1} )$$

for animation. For example, generating time-dependent visualizations to observe how flow patterns evolve over time, which is particularly useful for transient flows or unsteady simulations.

The largest vectors handled by the classical computer are θᵥ, which are of size [symbol] (log(N_{grid})). This size is much smaller than [symbol] (N_{grid}) required in classical CFD, which is the source of potential quantum advantage, and the price paid is that the complete solution of size [symbol] (N_{grid}) is unavailable on the classical computer 200. However, such full knowledge is seldom necessary because CFD analyses usually seek integral quantities of size [symbol] (1) (e.g., the lift and drag coefficients in an airplane simulation), which can be efficiently calculated from |f̅ᵥ [symbol] on the quantum computer 700 and sent to the classical computer 200.

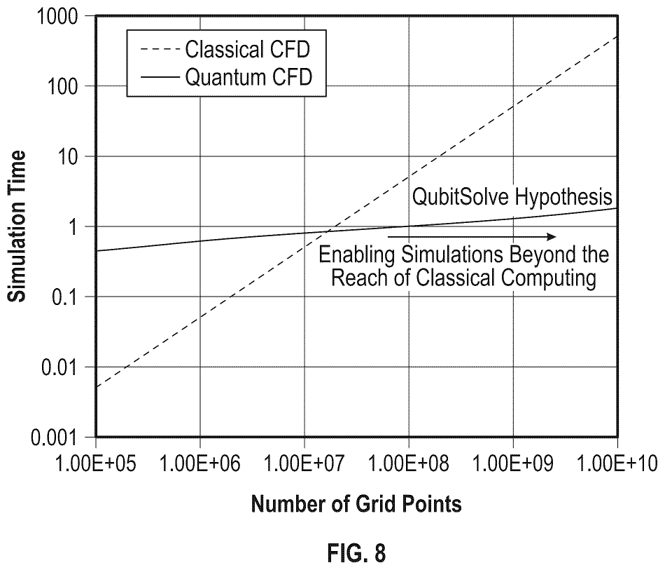

FIG. 8 is a graph that illustrates the advantage provided by the system of FIG. 1 for CFD simulations. A normalized simulation time is shown on the y-axis, and the number of grid points (N_{grid}) is on the x-axis. The simulation time for classical CFD is [symbol] (N_{grid}) and for quantum CFD it is estimated to be [symbol] (log²(N_{grid})). It is expected that for small values of N_{grid} the quantum CFD will be slower than classical CFD. When N_{grid} is large, quantum CFD becomes more efficient than classical CFD as the simulation time for quantum CFD increases at a slower rate. Thus, at N_{grid} greater than a cross-over point (arbitrarily shown as 20 million in FIG. 8), quantum CFD will be faster. Thus, quantum CFD of system 100 provides the technical benefit of speeding up simulations and enabling currently impossible simulations.

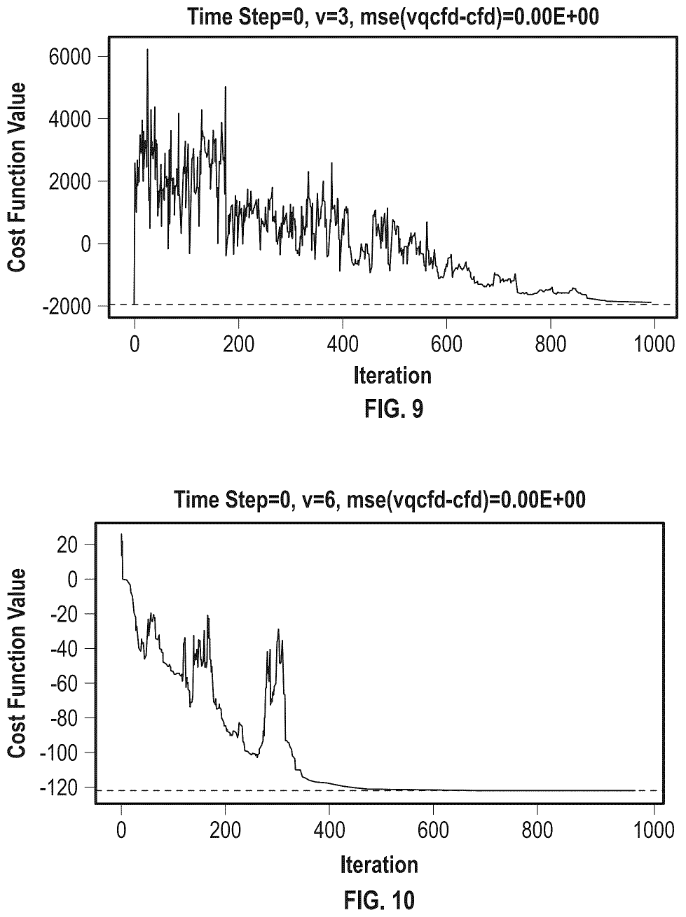

Referring to FIGS. 9 and 10, graphs illustrating examples of how the optimizer 722 (FIG. 7) reduces cost function values for two field variables are shown. The dashed lines show the exact minimum value calculated with the classical CFD code, to which the iterations converge with high accuracy. FIGS. 9 and 10 demonstrate that the partial differential equations underlying CFD can indeed be solved on quantum computers using the disclosed system 100.

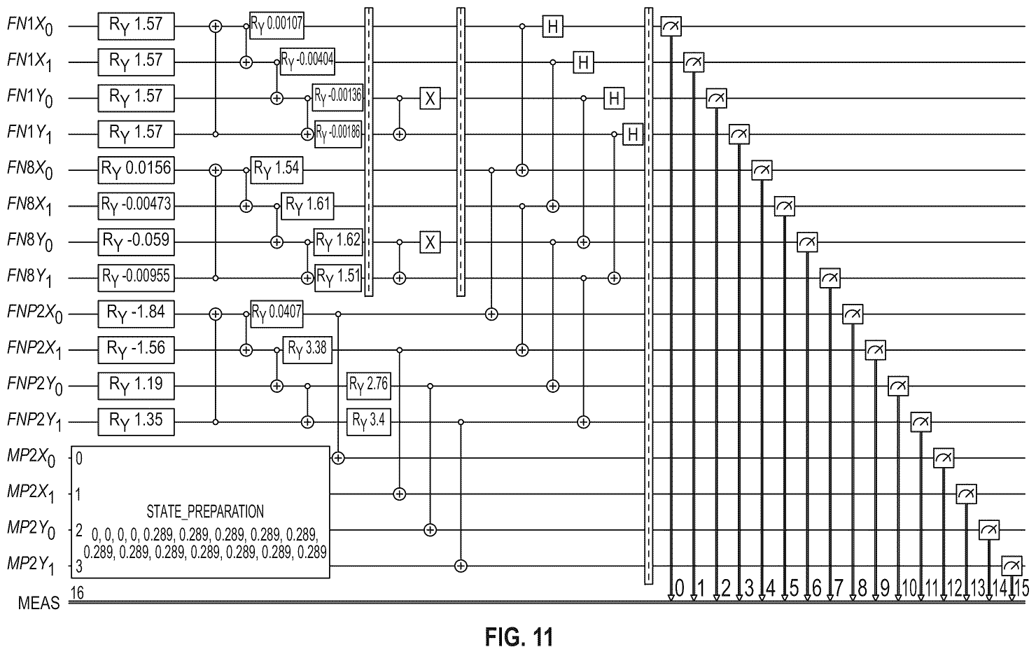

Referring to FIG. 11 an example of a quantum circuit that combines all the operations 711, 712, 713, 714, and 715 is shown. Such circuits are run on the quantum computer 700 to calculate the inner products.

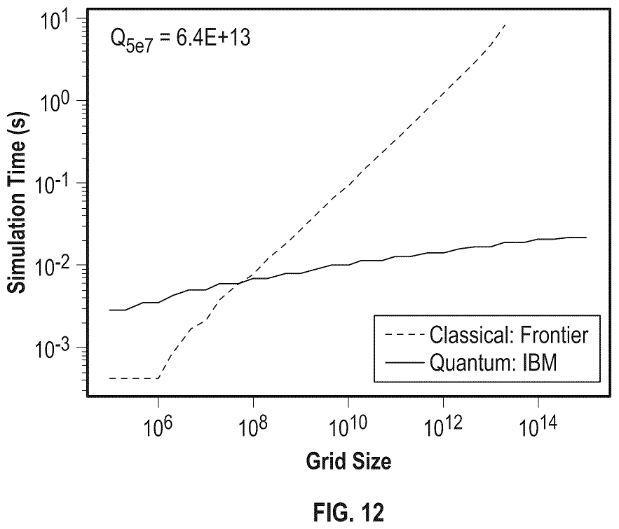

Referring to FIG. 12 a graph illustrating a comparison between classical CFD and the variational quantum CFD (VQCFD) used by system 100 of FIG. 1 is shown. The VQCFD performance, based on data from IonQ® and IBM® quantum computers, is scaled by Q₅ₑ₇, the ratio of quantum to classical simulation time for a grid size of fifty million, a typical grid size used in industrial CFD simulations. The classical CFD performance assumes the optimal performance of our CFD code on the Frontier supercomputer. The current estimate of Q₅ₑ₇ is necessarily very pessimistic as an unoptimized software prototype is compared to an optimized simulation on the world's fastest classical computer. The classical CFD curve ends where the Frontier supercomputer runs out of memory. VQCFD, as used by system 100, can go beyond that point on quantum computers like IBM® Condor.

Certain aspects of the present disclosure may include some, all, or none of the above advantages and/or one or more other advantages readily apparent to those skilled in the art from the drawings, descriptions, and claims included herein. Moreover, while specific advantages have been enumerated above, the various aspects of the present disclosure may include all, some, or none of the enumerated advantages and/or other advantages not specifically enumerated above.

The aspects disclosed herein are examples of the disclosure and may be embodied in various forms. For example, although certain aspects herein are described as separate aspects, each of the aspects herein may be combined with one or more of the other aspects herein. Specific structural and functional details disclosed herein are not to be interpreted as limiting, but as a basis for the claims and as a representative basis for teaching one skilled in the art to variously employ the present disclosure in virtually any appropriately detailed structure. Like reference numerals may refer to similar or identical elements throughout the description of the figures.

The phrases “in an aspect,” “in aspects,” “in various aspects,” “in some aspects,” or “in other aspects” may each refer to one or more of the same or different example aspects provided in the present disclosure. A phrase in the form “A or B” means “(A), (B), or (A and B).” A phrase in the form “at least one of A, B, or C” means “(A); (B); (C); (A and B); (A and C); (B and C); or (A, B, and C).”

It should be understood that the foregoing description is only illustrative of the present disclosure. Various alternatives and modifications can be devised by those skilled in the art without departing from the disclosure. Accordingly, the present disclosure is intended to embrace all such alternatives, modifications, and variances. The aspects described with reference to the attached drawing figures are presented only to demonstrate certain examples of the disclosure. Other elements, steps, methods, and techniques that are insubstantially different from those described above and/or in the appended claims are also intended to be within the scope of the disclosure.

What is claimed is:

1. A system for simulating fluid dynamics on quantum computers, the system comprising:
a quantum computer;
a processor; and
a memory, including instructions stored thereon, which, when executed by the processor, cause the system to:
access initial conditions
$$( {θ}_{v}^{0} , {Θ}_{v}^{0} )$$
and boundary conditions
$$( {θ}_{v}^{b} , {Θ}_{v}^{b} ) ;$$
generate
$$\vert {\overline{{f}_{v}}}^{n} 〉$$
based on
$${θ}_{v}^{n}$$
by the quantum computer;
generate
$$\vert {\overline{{f}_{v}}}^{b} 〉$$
based on
$${θ}_{v}^{b}$$
by the quantum computer;
receive by the quantum computer values of
$${θ}_{v , new}^{n + 1}$$
from an optimizer and generate tentative values of
$$\vert {\overline{{f}_{v}}}^{n + 1} 〉$$
based on
$${θ}_{v , new}^{n + 1} ;$$
generate by the quantum computer
$$〈 ( {\overline{{f}_{v}}}^{n} ) \vert {\overline{{f}_{v}}}^{n + 1} 〉$$
based on
$$\vert {\overline{{f}_{v}}}^{n} 〉$$
and the tentative values of
$$\vert {\overline{f}}_{v}^{n + 1} 〉 ;$$
generate by the quantum computer
$$〈 {\overline{f}}_{v}^{b} \vert {\overline{f}}_{v}^{n + 1} 〉$$
based on
$$\vert {\overline{f}}_{v}^{b} 〉$$
and the tentative values of
$$\vert {\overline{f}}_{v}^{n + 1} 〉 ;$$
determine cost function values Cᵥ based on a new value of
$${Θ}_{v , new}^{n + 1} ,$$
inner products
$$〈 {\overline{f}}_{v}^{b} \vert {\overline{f}}_{v}^{n + 1} 〉 ,$$
and
$$〈 ( {\overline{f}}_{v}^{n} ) \vert {\overline{f}}_{v}^{n + 1} 〉 ;$$
and
determine, by the optimizer, values for
$$( {θ}_{v}^{n + 1} , {Θ}_{v}^{n + 1} )$$
based on the cost function values Cᵥ.

2. The system of claim 1, wherein the instructions, when executed by the processor further cause the system to:
generate a visualization based on
$$( {θ}_{v}^{n + 1} , {Θ}_{v}^{n + 1} ) .$$

3. The system of claim 1, wherein initial conditions
$$( {θ}_{v}^{0} , {Θ}_{v}^{0} )$$
and boundary conditions
$$( {θ}_{v}^{b} , {Θ}_{v}^{b} )$$
are determined by:
accessing a grid representing a fluid flow around an object, wherein the grid includes N_{grid} grid points, wherein initial values for velocity (uᵢ) and density (ρ) are assigned at every grid point; and
performing transformations to convert velocity (uᵢ) and density (ρ) into initial conditions
$$( {θ}_{v}^{0} , {Θ}_{v}^{0} )$$
and boundary conditions
$$( {θ}_{v}^{b} , {Θ}_{v}^{b} ) .$$

4. The system of claim 3, wherein performing transformations to convert velocity (uᵢ) and density (ρ) into the parameters that require solving is performed by:
solving for
$${f}_{v}^{n} \to {f}_{v}^{n + 1}$$
using Lattice Boltzmann Method (LBM), where fᵥ is the v^{th} discretized particle velocity distribution function.

5. The system of claim 1, wherein performing transformations to convert velocity (uᵢ) and density (ρ) into the parameters that require solving is further performed by:
recovering velocity (uᵢ) and density (ρ) from moments of fᵥ:ρ=Σᵥfᵥ, and
$${u}_{l} = \frac{1}{ρ} {\sum }_{v} {c}_{lv} {f}_{v} ,$$
where cₗᵥ is the lattice-particle velocity.

6. The system of claim 1, wherein a plurality of
$$\vert {\overline{{f}_{v}}}^{n + 1} 〉$$
are generated.

7. The system of claim 1, wherein generating tentative values of
$$\vert {\overline{{f}_{v}}}^{n + 1} 〉$$
uses the Lattice Boltzmann Method (LBM) to solve for
$${f}_{v}^{n} \to {f}_{v}^{n + 1} ,$$
where fᵥ is a v^{th} discretized particle velocity distribution function.

8. The system of claim 1, wherein when generating tentative values of
$$\vert {\overline{{f}_{v}}}^{n + 1} 〉$$
the instructions, when executed by the processor, further cause the system to:
recover the CFD variables from the moments of fᵥ:ρ=Σᵥfᵥ, and
$${u}_{l} = \frac{1}{ρ} {\sum }_{v} {c}_{l v} {f}_{v} ,$$
where cₗᵥ is the lattice-particle velocity.

9. The system of claim 8, wherein when generating tentative values of
$$\vert {\overline{{f}_{v}}}^{n + 1} 〉$$
the instructions, when executed by the processor, further cause the system to:
encode fᵥ into the amplitudes of a quantum state.

10. The system of claim 9, wherein when generating tentative values of
$$\vert {\overline{{f}_{v}}}^{n + 1} 〉$$
the instructions, when executed by the processor, further cause the system to:
normalize values of fᵥ as f̅ₖᵥ=fₖᵥ/Θᵥ, where fₖᵥ is the value of fᵥ at grid point k, and Θᵥ is a 2-norm; and
encode fᵥ as:
$$\vert \overline{{f}_{v}} 〉 = {\sum }_{k = 0}^{{2}^{{N}_{q} - 1}} {\overline{f}}_{k v} \vert k 〉 ,$$
where N_{q}≈log(N_{grid}) and |k [symbol] is a k^{th} computational basis state.

11. A processor-implemented method for simulating fluid dynamics on quantum computers, the method comprising:
accessing initial conditions
$$( {θ}_{v}^{0} , {Θ}_{v}^{0} )$$
and boundary conditions
$$( {θ}_{v}^{b} , {Θ}_{v}^{b} ) ;$$
generating
$$\vert {\overline{{f}_{v}}}^{n} 〉$$
based on
$${θ}_{v}^{n}$$
by a quantum computer;
generating
$$\vert {\overline{{f}_{v}}}^{b} 〉$$
based on
$${θ}_{v}^{b}$$
by the quantum computer;
receiving by the quantum computer values of
$${θ}_{v , new}^{n + 1}$$
from an optimizer and generate tentative values of
$$\vert {\overline{f}}_{v}^{n + 1} 〉$$
based on
$${θ}_{v , new}^{n + 1} ;$$
generating by the quantum computer
$$〈 ( {\overline{f}}_{v}^{n} ) \vert {\overline{f}}_{v}^{n + 1} 〉$$
based on
$$\vert {\overline{f}}_{v}^{n} 〉$$
and the tentative values of
$$\vert {\overline{f}}_{v}^{n + 1} 〉 ;$$
generating by the quantum computer
$$〈 {\overline{f}}_{v}^{b} \vert {\overline{f}}_{v}^{n + 1} 〉$$
based on
$$\vert {\overline{f}}_{v}^{b} 〉$$
and the tentative values of
$$\vert {\overline{f}}_{v}^{n + 1} 〉 ;$$
determining cost function values Cᵥ based on a new value of
$${Θ}_{v , new}^{n + 1} ,$$
inner products
$$〈 {\overline{f}}_{v}^{b} \vert {\overline{f}}_{v}^{n + 1} 〉 ,$$
and
$$〈 ( {\overline{f}}_{v}^{n} ) \vert {\overline{f}}_{v}^{n + 1} 〉 ;$$
and
determining, by the optimizer, values for
$$( {θ}_{v}^{n + 1} , {Θ}_{v}^{n + 1} )$$
based on the cost function values Cᵥ.

12. The processor-implemented method of claim 11, further comprising:
generating a visualization based on
$$( {θ}_{v}^{n + 1} , {Θ}_{v}^{n + 1} ) .$$

13. The processor-implemented method of claim 11, further comprising:
determining initial conditions
$$( {θ}_{v}^{0} , {Θ}_{v}^{0} )$$
and boundary conditions
$$( {θ}_{v}^{b} , {Θ}_{v}^{b} )$$
by:
accessing a grid representing a fluid flow around an object, wherein the grid includes N_{grid} grid points, wherein initial values for velocity (uᵢ) and density (ρ) are assigned at every grid point; and
performing transformations to convert velocity (uᵢ) and density (ρ) into initial conditions
$$( {θ}_{v}^{0} , {Θ}_{v}^{0} )$$
and boundary conditions
$$( {θ}_{v}^{b} , {Θ}_{v}^{b} ) .$$

14. The processor-implemented method of claim 3, wherein performing transformations to convert velocity (uᵢ) and density (ρ) is performed by:
solving for
$${f}_{v}^{n} \to {f}_{v}^{n + 1}$$
using Lattice Boltzmann Method (LBM), where fᵥ is the v^{th} discretized particle velocity distribution function.

15. The processor-implemented method of claim 1, wherein performing transformations to convert velocity (uᵢ) and density (ρ) into the parameters is further performed by:
recovering velocity (uᵢ) and density (ρ) from moments of fᵥ:ρ=Σᵥfᵥ, and
$${u}_{l} = \frac{1}{ρ} {\sum }_{v} {c}_{lv} {f}_{v} ,$$
where cₗᵥ is the lattice-particle velocity.

16. The processor-implemented method of claim 1, wherein generating tentative values of
$$\vert {\overline{{f}_{v}}}^{n + 1} 〉$$
uses the Lattice Boltzmann Method (LBM) to solve for
$${f}_{v}^{n} \to {f}_{v}^{n + 1} ,$$
where fᵥ is a v^{th} discretized particle velocity distribution function.

17. The processor-implemented method of claim 1, wherein when generating tentative values of
$$\vert {\overline{{f}_{v}}}^{n + 1} 〉$$
the method further comprises:
recovering the CFD variables from the moments of fᵥ:ρ=Σᵥfᵥ, and
$${u}_{l} = \frac{1}{ρ} {\sum }_{v} {c}_{lv} {f}_{v} ,$$
where cₗᵥ is the lattice-particle velocity.

18. The processor-implemented method of claim 17, wherein when generating tentative values of
$$\vert {\overline{{f}_{v}}}^{n + 1} 〉$$
the method further comprises:
encoding fᵥ into the amplitudes of a quantum state.

19. The processor-implemented method of claim 18, wherein when generating tentative values of
$$\vert {\overline{{f}_{v}}}^{n + 1} 〉$$
the method further comprises:
normalizing values of fᵥ as f̅ₖᵥ=fₖᵥ/Θᵥ, where fₖᵥ is the value of fᵥ at grid point k, and Θᵥ is a 2-norm; and
encoding fᵥ as:
$$\vert \overline{{f}_{v}} 〉 = {\sum }_{k = 0}^{{2}^{{N}_{q} - 1}} {\overline{f}}_{k v} \vert k 〉 ,$$
where N_{q}≈log(N_{grid}) and |k [symbol] is a k^{th} computational basis state.

20. A non-transitory computer-readable storage medium storing a program for simulating fluid dynamics on quantum computers, the method comprising:
accessing initial conditions
$$( {θ}_{v}^{0} , {Θ}_{v}^{0} )$$
and boundary conditions
$$( {θ}_{v}^{b} , {Θ}_{v}^{b} ) ;$$
generating
$$\vert {\overline{{f}_{v}}}^{n} 〉$$
based on
$${θ}_{v}^{n}$$
by a quantum computer;
generating
$$\vert {\overline{{f}_{v}}}^{b} 〉$$
based on
$${θ}_{v}^{b}$$
by the quantum computer;
receiving by the quantum computer values of
$${θ}_{v , new}^{n + 1}$$
from an optimizer and generate tentative values of
$$\vert {\overline{{f}_{v}}}^{n + 1} 〉$$
based on
$${θ}_{v , new}^{n + 1} ;$$
generating by the quantum computer
$$〈 ( {\overline{{f}_{v}}}^{n} ) \vert {\overline{{f}_{v}}}^{n + 1} 〉$$
based on
$$\vert {\overline{{f}_{v}}}^{n} 〉$$
and the tentative values of
$$\vert {\overline{{f}_{v}}}^{n + 1} 〉 ;$$
generating by the quantum computer
$$( {\overline{{f}_{v}}}^{b} \vert {\overline{{f}_{v}}}^{n + 1} 〉$$
based on
$$\vert {\overline{{f}_{v}}}^{b} 〉$$
and the tentative values of
$$\vert {\overline{{f}_{v}}}^{n + 1} 〉 ;$$
determining cost function values Cᵥ based on a new value of
$${Θ}_{v , new}^{n + 1} ,$$
inner products
$$( {\overline{{f}_{v}}}^{b} \vert {\overline{{f}_{v}}}^{n + 1} 〉 ,$$
and
$$( ( {\overline{{f}_{v}}}^{n} ) \vert {\overline{{f}_{v}}}^{n + 1} 〉$$
and
determining, by the optimizer, values for
$$( {θ}_{v}^{n + 1} , {Θ}_{v}^{n + 1} )$$
based on the cost function values Cᵥ.
